(19) United States
(12) Patent Application Publication
(10) Pub. No.: US 2009/0283900 A1
(43) Pub. Date: Nov. 19, 2009

(54) SEMICONDUCTOR DEVICE AND MANUFACTURING METHOD FOR SEMICONDUCTOR DEVICE

(75) Inventor: Yuichiro YAMADA, Osaka (JP)

Correspondence Address: STEPTOE & JOHNSON LLP, 1330 CONNECTICUT AVE., NW, WASHINGTON, DC, 20036, US

(73) Assignee: Panasonic Corporation, Kadoma-shi (JP)

(21) Appl. No.: 12/432,791

(22) Filed: Apr. 30, 2009

(30) Foreign Application Priority Data
May 15, 2008 (JP) 2008-127784
Jan. 16, 2009 (JP) 2009-007115

(51) Int. Cl. H01L 23/04; H01L 21/00

(52) U.S. Cl. 257/698; 438/127; 257/E23.181; 257/E21.001

(57) ABSTRACT

A semiconductor device comprises: (a) a wiring board having front surface lands disposed on a front surface and rear surface lands disposed on a rear surface; (b) a semiconductor chip formed with an integrated circuit and electrode terminals electrically connected to the integrated circuit; and (c) a sealing resin that covers a front side of the wiring board when the semiconductor chip is mounted on the front side of the wiring board such that the front surface lands and the rear surface lands are electrically connected to the electrode terminals, wherein (d) holes having a shape and dimensions that allow projecting electrodes of the other semiconductor device to be inserted therein are formed in the sealing resin such that the front surface lands disposed further toward an inner side than a front surface of the semiconductor chip are exposed.

### BACKGROUND OF THE INVENTION

1. Field of the Invention

The present invention relates to a semiconductor device on which another semiconductor device can be stacked, and more particularly to a semiconductor device with which a PoP type semiconductor device can be constructed easily and at low cost and in which the reliability of a joint part between the semiconductor device and another semiconductor device is high.

2. Description of the Related Art

Conventionally, a Package on Package type (to be referred to hereafter as a “PoP type”) semiconductor device is used in cellular telephones, digital cameras, portable personal computers, and so on. A semiconductor device suitable for three-dimensional mounting is used in a PoP type semiconductor device. Various semiconductor devices in which an upper portion of a projecting electrode used for lamination purposes is exposed have been proposed as a semiconductor device suitable for three-dimensional mounting.

### First Example

For example, a semiconductor device in which a pattern wiring portion of a wiring is exposed on a rear surface of a sealing resin and another end of a post portion of the wiring is exposed on a front surface of the sealing resin such that similar semiconductor devices can be stacked has been proposed (see Japanese Unexamined Patent Application Publication No. 2007-59557, for example).

In the semiconductor device according to the first example, the wiring is constituted by the pattern wiring portion and the post portion. The wiring and a semiconductor chip are sealed by the sealing resin. The pattern wiring portion is connected to the semiconductor chip and exposed on the rear surface of the sealing resin. The post portion is formed in a thickness direction of the sealing resin. One end of the post portion is connected to the pattern wiring portion, and the other end of the post portion is exposed on the front surface of the sealing resin. A resin substrate required conventionally is not necessary. Therefore, reductions in thickness and cost can be achieved.

### Second Example

Further, a semiconductor device with which an electric signal test can be performed on a similar semiconductor device stacked on the semiconductor device has been proposed (see Japanese Unexamined Patent Application Publication No. 2007-335907, for example).

In the semiconductor device according to the second example, a first connection terminal is disposed on a rear surface of a substrate, and a semiconductor chip and a second connection terminal are disposed on a front surface of the substrate. The semiconductor chip and a side face of the second connection terminal are sealed by a sealing resin. An end face of the second connection terminal exposed from the sealing resin is flush with a surface of the sealing resin. Thus, a reduction in size can be achieved.

### Third Example

Further, a semiconductor device in which a lower surface connection electrode and an exposed end of a wiring are disposed on a mother board as upper and lower connection terminals, respectively, such that high-density mounting can be realized easily has been proposed (see Japanese Unexamined Patent Application Publication No. 2002-158312, for example).

In the semiconductor device according to the third example, a first wiring pattern provided on a front surface of a wiring board is connected to a second wiring pattern provided on a rear surface of the wiring board. A semiconductor chip is mounted on the front surface of the wiring board, connected to the first wiring pattern, and sealed by a sealing resin. A wiring is formed in a thickness direction of the sealing resin layer. One end of the wiring is connected to the first wiring pattern, and another end of the wiring is exposed from the front surface of the sealing resin layer. The lower surface connection electrode is formed on the rear surface of the wiring board and electrically connected to the second wiring pattern.

However, the conventional techniques described above have the following problems.

(Problem 1)

First, in the semiconductor device according to the first example, the surface area of the post portion increases toward the front surface of the sealing resin, and it is therefore difficult to form the post portion using multiple pins at a narrow pitch. Moreover, the number of steps is large, thick plating takes time, and cost is high.

The reason for this is that an opening portion formed in a photoresist film through photolithography exposure and development processing decreases toward a lower side. Moreover, as the thickness of the photoresist film increases and the depth of the opening portion increases, a difference in the opening area of the opening portion between the lower side and an upper side increases.

In the semiconductor device according to the first example, a photoresist film is formed on an upper layer of the pattern wiring portion to a thickness that is sufficiently higher than the loop height of a thin metallic wire stretched between the semiconductor chip and the pattern wiring portion. An opening portion is then formed in the photoresist film through photolithography exposure and development processing in an upper layer part of a post portion formation position of the pattern wiring portion until the opening portion reaches the post portion formation position. The post portion is then formed by plating in the thickness direction of the photoresist film while restricting the shape of the post portion by means of a side wall of the opening portion. A solder resist layer is then formed on the front surface and rear surface.

Hence, in the semiconductor device according to the first example, the thickness of the photoresist film exhibits an increasing tendency, and therefore the surface area of the post portion is likely to increase toward the front surface.

(Problem 2)

In the semiconductor device according to the second example, when a plurality of similar semiconductor devices are stacked, the mounting height increases in proportion to the height of a projecting electrode of the stacked similar semiconductor devices, and as a result, a reduction in height cannot be achieved.

The reason for this is that the end surface of the second connection terminal, which is fixed on the projecting electrode of the stacked semiconductor device, is flush with the surface of the sealing resin, and therefore the projecting electrode projects from the surface of the sealing resin.

(Problem 3)

In the semiconductor device according to the third example, a similar problem to that of the semiconductor device according to the second example occurs, and in addition, an increase in cost occurs for formation of the wiring in the thickness direction of the sealing resin layer.

The reason for this is that it is necessary to perform a step for forming a through hole extending to the first wiring pattern by applying laser light or the like from the front surface of the sealing resin layer and a step for filling the through hole with solder using a plating method or the like.

### SUMMARY OF THE INVENTION

The present invention has been designed in consideration of the problems described above, and it is an object thereof to provide a semiconductor device on which another semiconductor device can be mounted using multiple pins at a narrow pitch while suppressing the overall height, and which can be realized at low cost.

To achieve the object described above, a semiconductor device according to the present invention includes the following features.

(CL1) A semiconductor device according to the present invention is (a) a semiconductor device on which another semiconductor device can be stacked, and includes: (b) a wiring board having a plurality of front surface lands disposed on a front surface and a plurality of rear surface lands disposed on a rear surface; (c) a semiconductor chip formed with an integrated circuit and a plurality of electrode terminals electrically connected to the integrated circuit; and (d) a sealing resin that covers a front side of the wiring board when the semiconductor chip is mounted on the front side of the wiring board such that the plurality of front surface lands and the plurality of rear surface lands are electrically connected to the plurality of electrode terminals, wherein (e) a recess portion having a shape and dimensions that allow a plurality of projecting electrodes of the other semiconductor device to be inserted therein is formed in the sealing resin such that the plurality of front surface lands disposed further toward an inner side than a front surface of the semiconductor chip are exposed.

Hence, the plurality of projecting electrodes of the other semiconductor device can be dropped into the recess portion formed in the sealing resin, and as a result, the overall height of a PoP type semiconductor device can be suppressed. The reason for this is that when the PoP type semiconductor device is constructed, the plurality of projecting electrodes of the other semiconductor device are inserted in alignment with the recess portion and fixed on the plurality of front surface lands disposed at the bottom of the recess portion, and therefore the effect of the height of the plurality of projecting electrodes of the other semiconductor device on the overall height of the PoP type semiconductor device can be reduced.

(CL2) A semiconductor device according to the present invention is (a) a semiconductor device on which another semiconductor device can be stacked, and includes: (b) a wiring board having a plurality of front surface lands disposed on a front surface and a plurality of rear surface lands disposed on a rear surface; (c) a semiconductor chip formed with an integrated circuit and a plurality of electrode terminals electrically connected to the integrated circuit; (d) a plurality of platform electrodes formed on the plurality of front surface lands so as to correspond respectively to the plurality of front surface lands in pairs and project from the front surface of the wiring board; and (e) a sealing resin that covers a front side of the wiring board when the semiconductor chip is mounted on the front side of the wiring board such that the plurality of front surface lands and the plurality of rear surface lands are electrically connected to the plurality of electrode terminals, wherein (f) a recess portion having a shape and dimensions that allow a plurality of projecting electrodes of the other semiconductor device to be inserted therein is formed in the sealing resin such that the plurality of platform electrodes formed on the plurality of front surface lands disposed further toward an inner side than a front surface of the semiconductor chip are exposed.

Hence, the plurality of projecting electrodes of the other semiconductor device can be dropped into the recess portion formed in the sealing resin, and as a result, the overall height of the PoP type semiconductor device can be suppressed. The reason for this is that when the PoP type semiconductor device is constructed, the plurality of projecting electrodes of the other semiconductor device are inserted in alignment with the recess portion and fixed on the plurality of platform electrodes disposed at the bottom of the recess portion, and therefore the effect of the height of the plurality of projecting electrodes of the other semiconductor device on the overall height of the PoP type semiconductor device can be reduced. Furthermore, the depth of the recess portion can be adjusted by the plurality of platform electrodes such that even when the sealing resin must be formed thickly, the plurality of projecting electrodes of the other semiconductor device contact the plurality of platform electrodes.

Note that the present invention may be realized not only as a semiconductor device, but also as a manufacturing method for a semiconductor device including the following features.

(CL3) A manufacturing method for a semiconductor device according to the present invention is (a) a manufacturing method for a semiconductor device on which another semiconductor device can be stacked, and includes: (b) a first step for preparing a wiring board having a plurality of front surface lands disposed on a front surface and a plurality of rear surface lands disposed on a rear surface; (c) a second step for mounting a semiconductor chip formed with an integrated circuit and a plurality of electrode terminals electrically connected to the integrated circuit on a front side of the wiring board and electrically connecting the plurality of front surface lands and the plurality of rear surface lands to the plurality of electrode terminals; and (d) a third step for forming a sealing resin that covers the front side of the wiring board when the semiconductor chip is mounted on the front side of the wiring board such that the plurality of front surface lands and the plurality of rear surface lands are electrically connected to the plurality of electrode terminals using a compression molding method while pressing a front surface of the plurality of front surface lands against a release sheet possessing flexibility and elasticity, wherein (e) in the third step, a recess portion having a shape and dimensions that allow a plurality of projecting electrodes of the other semiconductor device to be inserted therein is formed in the sealing resin using a die having projecting portions corresponding respectively to the plurality of projecting electrodes in a cavity such that the plurality of front surface lands, which are disposed further toward an inner side than a front surface of the semiconductor chip, are exposed.

Hence, the sealing resin is formed using a compression molding method while the respective front surfaces of the plurality of front surface lands are pressed against the release sheet possessing flexibility and elasticity. Therefore, the sealing resin can be formed into a structure in which the front surface lands are exposed at the bottom of the recess portion easily. Moreover, the sealing resin is formed when the parts corresponding to the plurality of front surface lands are removed, thereby eliminating the need to perform deburring and cleaning on the sealing resin after a seal is formed.

(CL4) A manufacturing method for a semiconductor device according to the present invention is (a) a manufacturing method for a semiconductor device on which another semiconductor device can be stacked, and includes: (b) a first step for preparing a wiring board having a plurality of front surface lands disposed on a front surface and a plurality of rear surface lands disposed on a rear surface; (c) a second step for forming a plurality of platform electrodes that correspond respectively to the plurality of front surface lands in pairs and project from the front surface of the wiring board on the plurality of front surface lands; (d) a third step for mounting a semiconductor chip formed with an integrated circuit and a plurality of electrode terminals electrically connected to the integrated circuit on a front side of the wiring board and electrically connecting the plurality of front surface lands and the plurality of rear surface lands to the plurality of electrode terminals; and (e) a fourth step for forming a sealing resin that covers the front side of the wiring board when the semiconductor chip is mounted on the front side of the wiring board such that the plurality of front surface lands and the plurality of rear surface lands are electrically connected to the plurality of electrode terminals using a compression molding method while pressing a front surface of the plurality of platform electrodes against a release sheet possessing flexibility and elasticity, wherein (f) in the fourth step, a recess portion having a shape and dimensions that allow a plurality of projecting electrodes of the other semiconductor device to be inserted therein is formed in the sealing resin using a die having projecting portions corresponding respectively to the plurality of projecting electrodes in a cavity such that the plurality of platform electrodes formed on the plurality of front surface lands, which are disposed further toward an inner side than a front surface of the semiconductor chip, are exposed.

Hence, the sealing resin is formed using a compression molding method while the respective front surfaces of the plurality of platform electrodes are pressed against the release sheet possessing flexibility and elasticity. Therefore, the sealing resin can be formed into a structure in which the platform electrodes are exposed at the bottom of the recess portion easily. Moreover, the sealing resin is formed when the parts corresponding to the plurality of platform electrodes are removed, thereby eliminating the need to perform deburring and cleaning on the sealing resin after the seal is formed.

According to the present invention, the plurality of projecting electrodes of the other semiconductor device can be dropped into the recess portion formed in the sealing resin, and as a result, the overall height of the PoP type semiconductor device can be suppressed. The reason for this is that when the PoP type semiconductor device is constructed, the plurality of projecting electrodes of the other semiconductor device are inserted in alignment with the recess portion and fixed on the plurality of front surface lands or the plurality of platform electrodes disposed at the bottom of the recess portion, and therefore the effect of the height of the plurality of projecting electrodes of the other semiconductor device on the overall height of the PoP type semiconductor device can be reduced.

Further, the sealing resin is formed using a compression molding method while the respective front surfaces of the plurality of front surface lands or the plurality of platform electrodes are pressed against the release sheet possessing flexibility and elasticity. Therefore, the sealing resin can be formed into a structure in which the plurality of front surface lands or the plurality of platform electrodes are exposed at the bottom of the recess portion easily. Moreover, the sealing resin is formed when the parts corresponding to the plurality of front surface lands or the plurality of platform electrodes are removed, thereby eliminating the need to perform deburring and cleaning on the sealing resin after a seal is formed.

The present invention may be used as a semiconductor device on which another semiconductor device can be stacked or the like, and more particularly as a semiconductor device or the like with which a PoP type semiconductor device can be constituted easily and at low cost, and in which the reliability of a joint part between the semiconductor device and another semiconductor device is high.

### BRIEF DESCRIPTION OF THE DRAWINGS

These and other objects, advantages and features of the invention will become apparent from the following description thereof taken in conjunction with the accompanying drawings which illustrates a specific embodiment of the invention. In the drawings:

FIG. 1A is a partially cut-away perspective view of a semiconductor device according to a first embodiment;

FIG. 1B is a sectional view showing the semiconductor device according to the first embodiment when cut along a cutting line A-A;

FIG. 2A is a first sectional view showing a first-half step of a manufacturing method for the semiconductor device according to the first embodiment;

FIG. 2B is a second sectional view showing a first-half step of the manufacturing method for the semiconductor device according to the first embodiment;

FIG. 2C is a third sectional view showing a first-half step of the manufacturing method for the semiconductor device according to the first embodiment;

FIG. 3A is a first sectional view showing a second-half step of the manufacturing method for the semiconductor device according to the first embodiment;

FIG. 3B is a second sectional view showing a second-half step of the manufacturing method for the semiconductor device according to the first embodiment;

FIG. 3C is a third sectional view showing a second-half step of the manufacturing method for the semiconductor device according to the first embodiment;

FIG. 3D is a fourth sectional view showing a second-half step of the manufacturing method for the semiconductor device according to the first embodiment;

FIG. 4 is a sectional view showing the constitution of a PoP type semiconductor device employing the semiconductor device according to the first embodiment;

FIG. 5A is a partially cut-away perspective view of a semiconductor device according to a second embodiment;

FIG. 5B is a sectional view showing the semiconductor device according to the second embodiment when cut along a cutting line A-A;

FIG. 6A is a first sectional view showing a first-half step of a manufacturing method for the semiconductor device according to the second embodiment;

FIG. 6B is a second sectional view showing a first-half step of the manufacturing method for the semiconductor device according to the second embodiment;

FIG. 6C is a third sectional view showing a first-half step of the manufacturing method for the semiconductor device according to the second embodiment;

FIG. 6D is a fourth sectional view showing a first-half step of the manufacturing method for the semiconductor device according to the second embodiment;

FIG. 7A is a first sectional view showing a second-half step of the manufacturing method for the semiconductor device according to the second embodiment;

FIG. 7B is a second sectional view showing a second-half step of the manufacturing method for the semiconductor device according to the second embodiment;

FIG. 7C is a third sectional view showing a second-half step of the manufacturing method for the semiconductor device according to the second embodiment;

FIG. 7D is a fourth sectional view showing a second-half step of the manufacturing method for the semiconductor device according to the second embodiment;

FIG. 8 is a sectional view showing the constitution of a semiconductor device according to a third embodiment;

FIG. 9 is a sectional view showing the constitution of a semiconductor device according to a fourth embodiment;

FIG. 10A is a partially cut-away perspective view of a semiconductor device according to a fifth embodiment;

FIG. 10B is a sectional view showing the semiconductor device according to the fifth embodiment when cut along a cutting line A-A;

FIG. 11A is a partially cut-away perspective view of a semiconductor device according to a sixth embodiment; and

FIG. 11B is a sectional view showing the semiconductor device according to the sixth embodiment when cut along a cutting line A-A.

### DESCRIPTION OF THE PREFERRED EMBODIMENTS

### First Embodiment

A first embodiment of the present invention will be described below.

(Constitution)

First, the constitution of a semiconductor device according to this embodiment will be described. Note that for convenience, the thickness, length, number of electrodes, and so on of the various members shown in the drawings differ from reality.

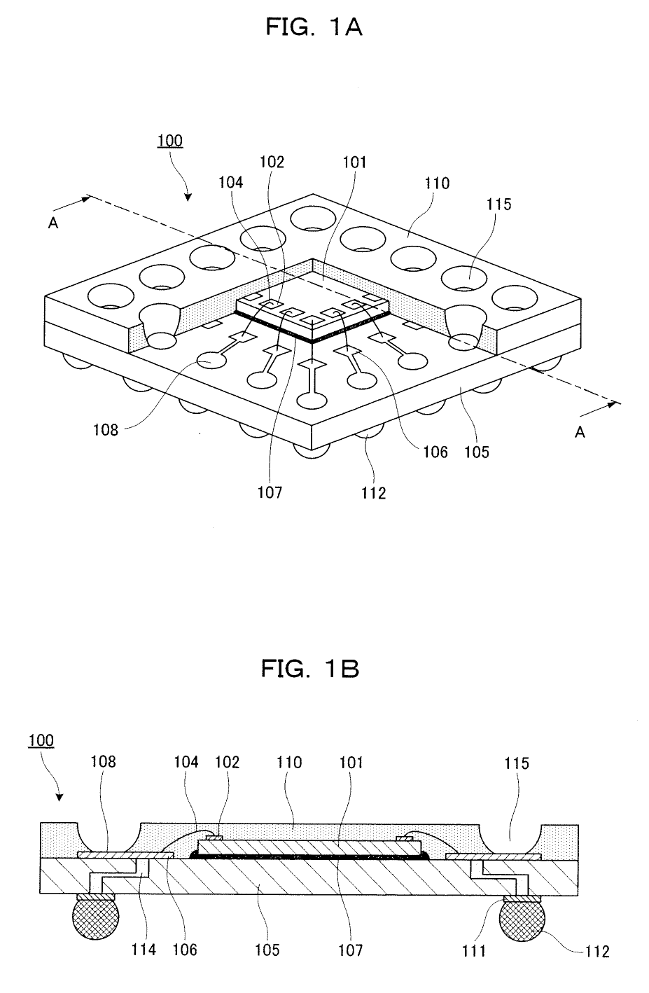

As shown in FIGS. 1A and 1B, a semiconductor device 100 is a semiconductor device on which another semiconductor device can be stacked. In this example, the semiconductor device 100 includes a semiconductor chip 101, a wiring board 105, a sealing resin 110, and a plurality of projecting electrodes 112.

Note that in FIG. 1A, a part of the sealing resin 110 has been removed to make the structure of the semiconductor device 100 easier to see.

(Semiconductor Chip 101)

The semiconductor chip 101 includes an integrated circuit (not shown) and a plurality of electrode terminals 102. Taking the side on which the plurality of electrode terminals 102 are disposed as a front side, the semiconductor chip 101 is mounted on a front surface central region of the wiring board 105 by an adhesive 107. Here, the plurality of electrode terminals 102 are disposed in a front surface outer peripheral region of the semiconductor chip 101 and electrically connected to the integrated circuit (not shown).

(Wiring Board 105)

The wiring board 105 includes a wiring pattern and a conductor. The wiring pattern is formed from a conductive film on both surfaces of the wiring board 105. The conductor is formed from a conductive film or conductive filler, and is electrically connected to the wiring patterns on both surfaces either directly or via an intermediate wiring layer. More specifically, the wiring pattern is constituted by a plurality of connection terminals 106 and a plurality of front surface lands 108 formed on the front surface (the upper side in the drawing) and a plurality of rear surface lands 111 formed on the rear surface (the lower side in the drawing). A plurality of vias 114 are formed as the conductor.

Here, the plurality of connection terminals 106 are disposed surrounding the region on which the semiconductor chip 101 is mounted (to be referred to hereafter as a semiconductor chip mounting region), and are electrically connected to the plurality of electrode terminals 102 via respective metallic thin wires 104. The plurality of front surface lands 108 are disposed surrounding the region in which the plurality of connection terminals 106 are formed, and are electrically connected to the plurality of connection terminals 106 via respective wiring pattern parts formed in a radial shape. The plurality of rear surface lands 111 are disposed in a rear surface outer peripheral region of the wiring board 105 and electrically connected to the plurality of connection terminals 106 via the respective vias 114. In other words, the plurality of front surface lands 108 and the plurality of rear surface lands 111 are electrically connected to the plurality of electrode terminals 102.

(Sealing Resin 110)

The sealing resin 110 is formed using a compression molding method to cover the front surface of the wiring board 105 until the semiconductor chip 101 and the metallic thin wires 104 are buried. The sealing resin 110 includes a plurality of holes 115 that correspond respectively to the plurality of front surface lands 108 to form pairs therewith.

Here, the plurality of holes 115 are formed in the sealing resin 110 with a shape and dimensions that allow the plurality of projecting electrodes (to be referred to hereafter as a plurality of external projecting electrodes) of another semiconductor device stacked on the semiconductor device 100 to be inserted therein and such that the plurality of front surface lands 108 disposed further toward the inner side than the front surface of the semiconductor chip 101 are exposed. An opening area of each hole 115 is larger than an exposed area of the front surface land 108. The cross-section of each hole 115 takes a narrowing shape having rounded sides such that an opening width is larger than a bottom width and the width decreases toward the front surface land 108 at the bottom of the hole 115. In other words, the plurality of holes 115 are formed in the sealing resin 110 to allow the plurality of external projecting electrodes to be fixed on the plurality of front surface lands 108.

(Projecting Electrode 112)

The plurality of projecting electrodes 112 are disposed to correspond respectively to the plurality of rear surface lands 111 so as to form pairs therewith, and are fixed on the exposed surface of the plurality of rear surface lands 111. Note that the plurality of projecting electrodes 112 are electrically connected to a packaging board (not shown).

(Manufacturing Method)

Next, a method of manufacturing the semiconductor device 100 will be described. Here, a single semiconductor device 100 will be described as an example for the sake of simplicity. In reality, however, a plurality of semiconductor devices 100 are manufactured at once using a multiple wiring board rather than manufacturing the semiconductor device 100 singly. In this case, the multiple wiring board is singularized by a dicer or laser either after the projecting electrodes 112 have been fixed on the rear surface lands 111 or before the projecting electrodes 112 are fixed on the rear surface lands 111.

In this example, the semiconductor device 100 is manufactured using a manufacturing method having the following steps (1) to (7). Note that representative dimensions, materials and so on are described in relation to each member of the semiconductor device 100, and the present invention is not limited thereto.

(Step 1)

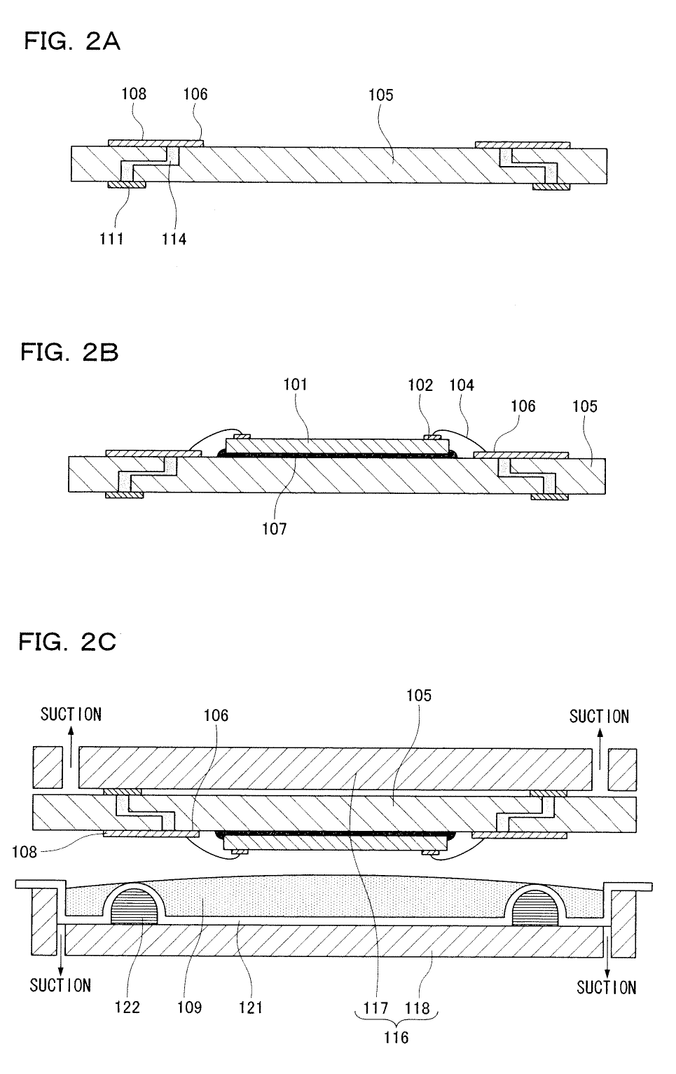

First, as shown in FIG. 2A, the wiring board 105 is prepared. Here, the thickness of the wiring board 105 is set within a range of 100 μm to 600 μm, and preferably at approximately 200 μm.

(Step 2)

Next, as shown in FIG. 2B, the semiconductor chip 101 is mounted on the semiconductor chip mounting region of the wiring board 105. Here, the base material of the semiconductor chip 101 is silicon. The thickness of the semiconductor chip 101 is set within a range of 50 μm to 200 μm, and preferably at approximately 100 μm. Gold wire is used for the metallic thin wires 104. The diameter of the metallic thin wire 104 is set within a range of 10 μm to 40 μm, and preferably at approximately 18 μm. The height of an apex of a loop formed by the metallic thin wire 104 is set within a range of 40 μm to 250 μm from the front surface of the wiring board 105, and preferably at approximately 100 μm.

At this time, the adhesive 107 is applied to the semiconductor chip mounting region of the wiring board 105. The semiconductor chip 101 is disposed on the surface coated with the adhesive 107. The wiring board 105 provided with the semiconductor chip 101 is heated in an inert gas atmosphere or a vacuum until the adhesive 107 hardens. Once the adhesive 107 has hardened, a wire bonding method is employed to connect one end of the metallic thin wire 104 to the electrode terminal 102 and the other end of the metallic thin wire 104 to the connection terminal 106.

(Step 3)

Next, as shown in FIG. 2C, a sealing resin material 109 is supplied to the wiring board 105 on which the semiconductor chip 101 is mounted. Here, a die 116 having a plurality of projections 122 formed in cavities to correspond respectively to the plurality of external projecting electrodes so as to form pairs therewith is used. A thermosetting epoxy resin is used as the sealing resin material 109. The thickness of a release sheet 121 is set within a range of 10 μm to 100 μm, and preferably at approximately 25 μm. The height of the projection 122 is set within a range of 10 μm to 400 μm, and preferably at approximately 200 μm. The cross-section of the projection 122 takes a narrowing shape having rounded sides such that the width of the base is larger than the width of the apex and the width decreases toward the apex.

At this time, a die temperature of the die 116 in a resin sealing compression molding machine is set at a temperature for melting the sealing resin material 109. The wiring board 105 mounted with the semiconductor chip 101 is disposed on an upper die 117 of the die 116 with the front side of the wiring board 105 facing downward. The release sheet 121, which possesses flexibility and elasticity and can be peeled from the sealing resin material 109, is disposed on a lower die 118 of the die 116 so as to cover the projections 122 formed in the cavity region. The wiring board 105 disposed on the upper die 117 is suctioned so as to be held by the upper die 117. The release sheet 121 disposed on the lower die 118 is suctioned into close contact with a molding surface of the lower die 118. The sealing resin material 109, which takes a granular form, is then supplied onto the release sheet 121 in the cavity region part of the lower die 118 in a predetermined amount required to form the resin seal.

(Step 4)

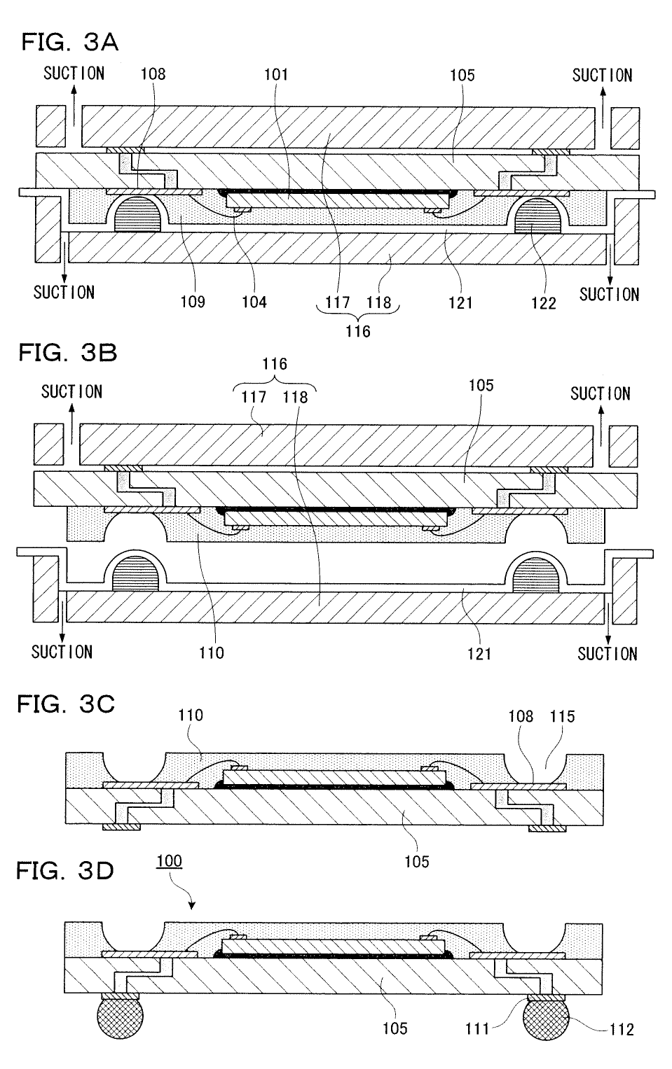

Next, as shown in FIG. 3A, the sealing resin material 109 is subjected to compression molding such that the front side of the wiring board 105 is resin-sealed. Here, the thickness of the sealing resin 110, or in other words a dimension from the front surface of the wiring board 105 to the front surface of the sealing resin 110, is set within a range of 120 μm to 400 μm, and preferably at approximately 200 μm.

At this time, an upper surface of the release sheet 121, which is in close contact with the molding surface of the lower die 118, raises the lower die 118 to a position of contact with the front surface of the wiring board 105 held by the upper die 117 while the interior of the cavity region of the lower die 118, in which the molten low-viscosity sealing resin material 109 has accumulated, is subjected to vacuum extraction. The semiconductor chip 101 and the metallic thin wires 104 are buried in the molten low-viscosity sealing resin material 109. A constant clamping pressure is applied to the lower die 118 until the sealing resin material 109 hardens, even after the release sheet 121 has contacted the wiring board 105. The plurality of projections 122 formed in the cavity region of the lower die 118 so as to oppose the front surface lands 108 contact the plurality of front surface lands 108 on the wiring board 105 via the release sheet 121 such that tip ends of the plurality of projections 122 are pressed against the plurality of front surface lands 108. The sealing resin 110 is thus formed such that the front surface of the front surface land 108 is exposed to the bottom of the hole 115.

(Step 5)

Next, as shown in FIG. 3B, after the sealing resin 110 has hardened, the lower die 118 is lowered to a height at which the wiring board 105 formed with the sealing resin 110 can be removed. When the lower die 118 is lowered, the release sheet 121 is peeled away easily from the sealing resin 110.

(Step 6)

Next, as shown in FIG. 3C, the plurality of holes 115, which are disposed in the wiring board 105 immediately after its removal from the die 116 so as to correspond respectively to the plurality of front surface lands 108 in pairs, are formed in the sealing resin 110. The cross-section of each hole 115 takes a narrowing shape having rounded sides such that the opening width is larger than the bottom width and the width decreases toward the front surface land 108 at the bottom of the hole 115.

(Step 7)

Next, as shown in FIG. 3D, the plurality of projecting electrodes 112 are fixed on the plurality of rear surface lands 111. Here, the projecting electrodes 112 are solder balls.

At this time, a solder paste layer is formed on the rear surface land 111 through solder printing. A solder ball is adsorbed by a ball adsorption device, whereupon the adsorbed solder ball is moved such that the rear surface land 111 and the solder ball are aligned. The solder ball is disposed on the solder paste layer on the rear surface land 111. The wiring board 105 provided with the solder ball is then passed through an inert gas atmosphere reflow furnace set at a temperature for melting the solder paste for a predetermined time period. Thus, the projecting electrode 112 is fixed on the rear surface land 111.

(Pop Type Semiconductor Device)

Next, a PoP type semiconductor device employing the semiconductor device 100 will be described.

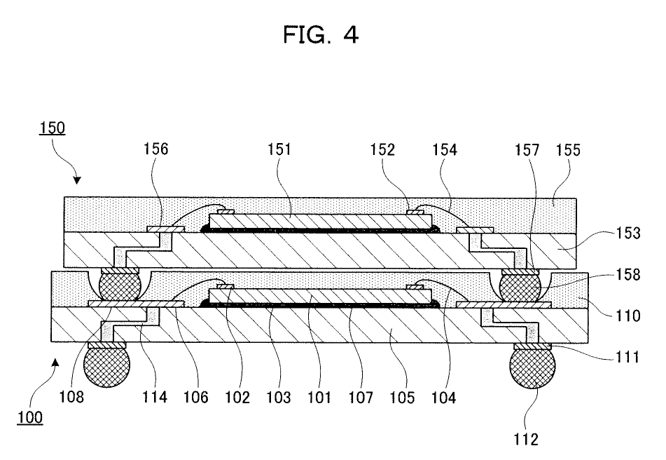

As shown in FIG. 4, in this example, a BGA (Ball Grid Array) type semiconductor device 150 is stacked on the semiconductor device 100.

The BGA type semiconductor device 150 includes a semiconductor chip 151, a wiring board 153, a sealing resin 155, and a plurality of projecting electrodes 158.

The semiconductor chip 151 includes an integrated circuit (not shown) and a plurality of electrode terminals 152. Taking the side on which the plurality of electrode terminals 152 are disposed as a front side, the semiconductor chip 151 is mounted on a front surface central region of the wiring board 153. Here, the plurality of electrode terminals 152 are disposed in a front surface outer peripheral region of the semiconductor chip 151 and electrically connected to the integrated circuit (not shown).

The wiring board 153 is formed with a plurality of connection terminals 156 on its front surface and a plurality of rear surface lands 157 on its rear surface. Here, the plurality of connection terminals 156 are disposed surrounding the region on which the semiconductor chip 151 is mounted, and are electrically connected to the plurality of electrode terminals 152 via respective metallic thin wires 154. The plurality of rear surface lands 157 are disposed to correspond respectively to the plurality of front surface lands 108 of the semiconductor device 100 so as to form pairs therewith, and are electrically connected to the plurality of connection terminals 156. Note that the plurality of rear surface lands 157 are electrically connected to the plurality of front surface lands 108.

The sealing resin 155 is formed using a compression molding method or a transfer molding method to cover the front surface of the wiring board 153 until the semiconductor chip 151 and the metallic thin wires 154 are buried.

The plurality of projecting electrodes 158 are disposed to correspond respectively to the plurality of rear surface lands 157 so as to form pairs therewith, and are mounted on the plurality of rear surface lands 157. Further, the plurality of projecting electrodes 158 are disposed to correspond respectively to the plurality of front surface lands 108 of the semiconductor device 100 so as to form pairs therewith, and are mounted on the plurality of front surface lands 108 by solder.

(Summary)

According to the embodiment described above, the plurality of external projecting electrodes can be dropped into the plurality of holes 115 formed in the sealing resin 110, and as a result, the overall height of the PoP type semiconductor device can be suppressed. The reason for this is that when the PoP type semiconductor device is constructed, the plurality of external projecting electrodes are inserted in alignment with the plurality of holes 115 and mounted on the plurality of front surface lands 108 disposed in the bottom of the plurality of holes 115, and therefore the effect of the height of the plurality of external projecting electrodes on the overall height of the PoP type semiconductor device can be reduced.

Furthermore, the solder paste that is used when the plurality of external projecting electrodes are fixed can be prevented from leaking out by the plurality of holes 115 formed in the sealing resin 110. Moreover, even when the plurality of external projecting electrodes are formed from multiple pins at a narrow pitch, short-circuits can be prevented from occurring in the front surface lands 108.

Further, the opening area of the hole 115 is larger than the exposed area of the front surface land 108. Moreover, the cross-section of the hole 115 takes a narrowing shape having rounded sides such that an opening width is larger than a bottom width and the width decreases toward the front surface land 108 at the bottom of the hole 115. Accordingly, the external projecting electrode can be guided to the front surface land 108 disposed in the bottom of the hole 115 easily. As a result, the plurality of external projecting electrodes can be fixed on the plurality of front surface lands 108 in an accurately positioned state. Furthermore, the external projecting electrode is led to the center of the front surface land 108 disposed in the bottom of the hole 115 while being guided by the side wall of the hole 115, and is therefore fixed on the front surface land 108 securely. Therefore, three-dimensional mounting can be achieved without mounting defects (open defects). Moreover, in comparison with a case in which a mounting defect (open defect) has occurred, the number of front surface lands 108 fixed securely on the external projecting electrodes is large, and therefore stress applied to the respective joint parts between the external projecting electrodes and the front surface lands 108 can be reduced while maintaining sufficient strength in the joint parts. In other words, the reliability of the joint parts between the external projecting electrodes and the front surface lands 108 can be improved.

Hence, it is possible to realize three-dimensional mounting in which height is suppressed, multi-pin/narrow pitch can be achieved, and mounting defects (open defects) do not occur. Moreover, it is possible to realize a PoP type semiconductor device in which the reliability of the joint parts is high.

Further, during manufacture of the semiconductor device 100, the metallic thin wires 104 are submerged in the sealing resin material 109, which has melted sufficiently to reach a low viscosity, at a low speed in (Step 4). Therefore, deformation of the metallic thin wires 104 due to resin flow can be prevented.

Furthermore, in the compression molding method, the sealing resin 110 is formed while the respective front surfaces of the plurality of front surface lands 108 are pressed against the flexible, elastic release sheet 121. Therefore, the sealing resin 110 can be formed into a structure in which the plurality of front surface lands 108 are exposed to the bottoms of the plurality of holes 115 easily. Moreover, the sealing resin 110 is formed when the parts corresponding to the plurality of front surface lands 108 are removed, thereby eliminating the need to perform deburring and cleaning on the sealing resin 110 after the seal is formed.

As a result, a reduction in manufacturing time, a reduction in the number of manufacturing steps, and a corresponding reduction in cost can be realized.

Note that when an FBGA (Fine pitch Ball Grid Array) type semiconductor device is stacked on the semiconductor device 100, the entire structure is substantially identical except for the part of the holes 115 formed in the sealing resin 110. Hence, when constructing a PoP type semiconductor device, the warping shapes of the respective semiconductor devices during reflow are different, and therefore mounting defects (open defects) do not occur.

Note that a PoP type semiconductor device is extremely effective in portable terminals and electrical home appliances requiring sharp reductions in size. The reason for this is that when a PoP type semiconductor device is used, the contents of the portable terminal or electrical home appliance can be packaged at high density, and therefore very small portable terminals and electrical home appliances can be realized.

### Second Embodiment

A second embodiment of the present invention will be described below.

(Constitution)

First, the constitution of a semiconductor device according to this embodiment will be described. Note that identical constitutional elements to the first embodiment have been allocated identical reference numerals, and description thereof has been omitted.

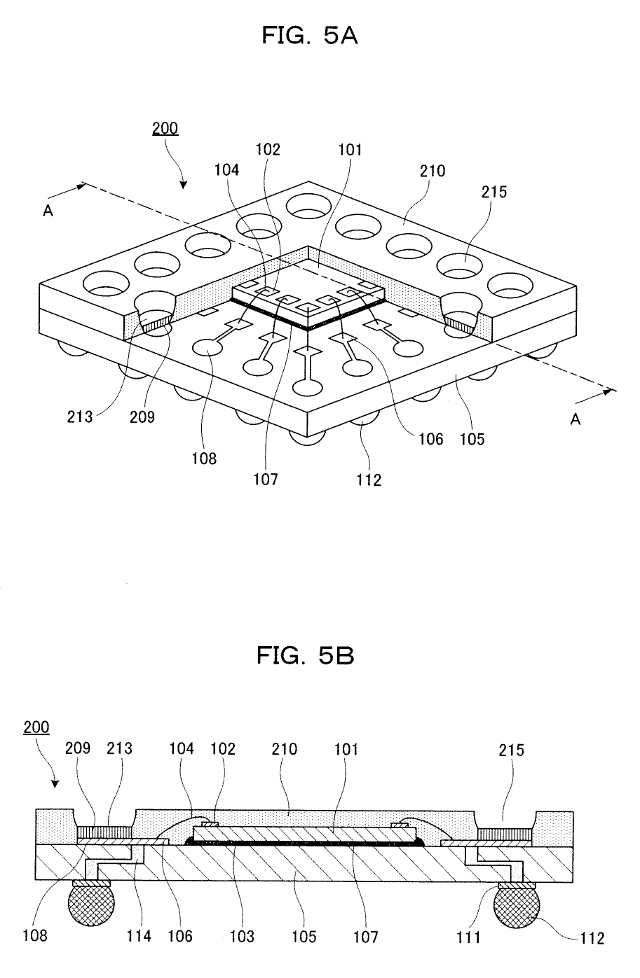

As shown in FIGS. 5A and 5B, a semiconductor device 200 differs from the semiconductor device 100 according to the first embodiment on the following points (1) and (2).

Note that in FIG. 5A, a part of an elevated electrode 209 and a sealing resin 210 has been removed to make the structure of the semiconductor device 200 easier to see.

(1) A plurality of platform electrodes 209 corresponding respectively to the plurality of front surface lands 108 to form pairs therewith are formed respectively on the front surface lands 108.

Here, the plurality of platform electrodes 209 are formed on the front surface lands 108 by solder so as to project from the front surface of the wiring board 105, and are electrically connected to the respective front surface lands 108. The height of a tip end portion 213 thereof is lower than the front surface of the sealing resin 210.

(2) A plurality of holes 215 corresponding respectively to the plurality of platform electrodes 209 to form pairs therewith are formed in the sealing resin 210.

Here, the plurality of holes 215 are formed in the sealing resin 210 with a shape and dimensions that allow the plurality of external projecting electrodes to be inserted therein and such that the plurality of platform electrodes 209 formed on the plurality of front surface lands 108 disposed further toward the inner side than the front surface of the semiconductor chip 101 are exposed. An opening area of each hole 215 is larger than an exposed area of the elevated electrode 209. The cross-section of each hole 215 takes a narrowing shape having rounded sides such that an opening width is larger than a bottom width and the width decreases toward the elevated electrode 209 at the bottom of the hole 215. In other words, the plurality of holes 215 are formed in the sealing resin 210 to allow the plurality of external projecting electrodes to be fixed on the plurality of platform electrodes 209.

(Manufacturing Method)

Next, a method of manufacturing the semiconductor device 200 will be described. Here, a single semiconductor device 200 will be described for the sake of simplicity. In reality, however, a plurality of semiconductor devices 200 are manufactured at once using a multiple wiring board rather than manufacturing the semiconductor device 200 singly. In this case, the multiple wiring board is singularized by a dicer or laser either after the projecting electrodes 112 have been formed on the rear surface lands 111 or before the projecting electrodes 112 are fixed on the rear surface lands 111.

In this example, the semiconductor device 200 is manufactured using a manufacturing method having the following steps (1) to (8). Note that representative dimensions, materials and so on are described in relation to each member of the semiconductor device 200, and the present invention is not limited thereto. Further, description relating to members that are identical to those of the first embodiment has been omitted.

(Step 1)

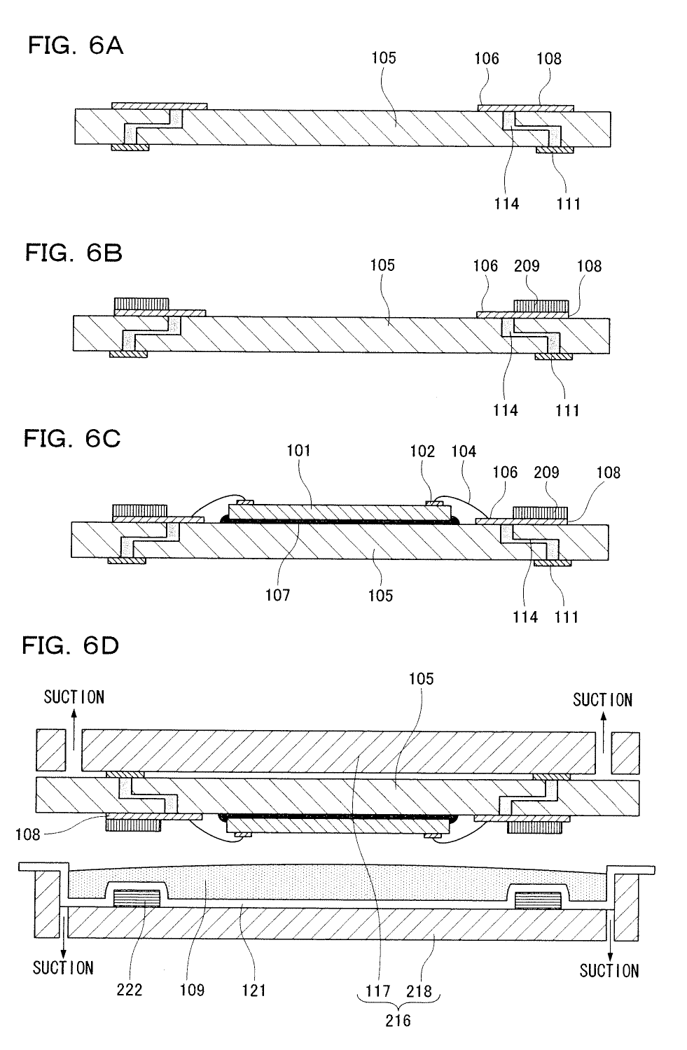

First, as shown in FIG. 6A, the wiring board 105 is prepared.

(Step 2)

Next, as shown in FIG. 6B, the platform electrodes 209 are formed on the front surface lands 108 of the wiring board 105. Here, solder that can be deformed through pressurization is used as the material of the platform electrodes 209. A height from the front surface of the front surface land 108 to the tip end portion 213 of the elevated electrode 209 is set within a range of 5 μm to 300 μm, and preferably at approximately 100 μm.

At this time, a solder paste layer is formed on the front surface land 108 through solder printing. The wiring board 105 provided with the solder paste layer is then passed through an inert gas atmosphere reflow furnace set at a temperature for melting the solder paste for a predetermined time period. Thus, the plurality of platform electrodes 209 are formed.

(Step 3)

Next, as shown in FIG. 6C, the semiconductor chip 101 is mounted on the semiconductor chip mounting region of the wiring board 105 on which the plurality of platform electrodes 209 are formed.

(Step 4)

Next, as shown in FIG. 6D, the sealing resin material 109 is supplied to the wiring board 105 on which the semiconductor chip 101 is mounted. Here, a die 216 having a plurality of projections 222 formed in cavities to correspond respectively to the plurality of external projecting electrodes so as to form pairs therewith is used. The height of the projection 222 is set within a range of 5 μm to 300 μm, and preferably at approximately 100 μm. The cross-section of the projection 222 takes a narrowing shape having rounded sides and a flat apex such that the width of the base is larger than the width of the apex and the width decreases toward the apex.

At this time, a die temperature of the die 216 in a resin sealing compression molding machine is set at a temperature for melting the sealing resin material 109. The wiring board 105 mounted with the semiconductor chip 101 is disposed on the upper die 117 of the die 216 with the front surface of the wiring board 105 facing downward. The release sheet 121, which possesses flexibility and elasticity and can be peeled from the sealing resin material 109, is disposed on a lower die 218 of the die 216 so as to cover the projections 222 formed in the cavity region. The wiring board 105 disposed on the upper die 117 is suctioned so as to be held by the upper die 117. The release sheet 121 disposed on the lower die 218 is suctioned into close contact with a molding surface of the lower die 218. The sealing resin material 109, which takes a granular form, is then supplied onto the release sheet 121 in the cavity region part of the lower die 218 in a predetermined amount required to form the resin seal.

(Step 5)

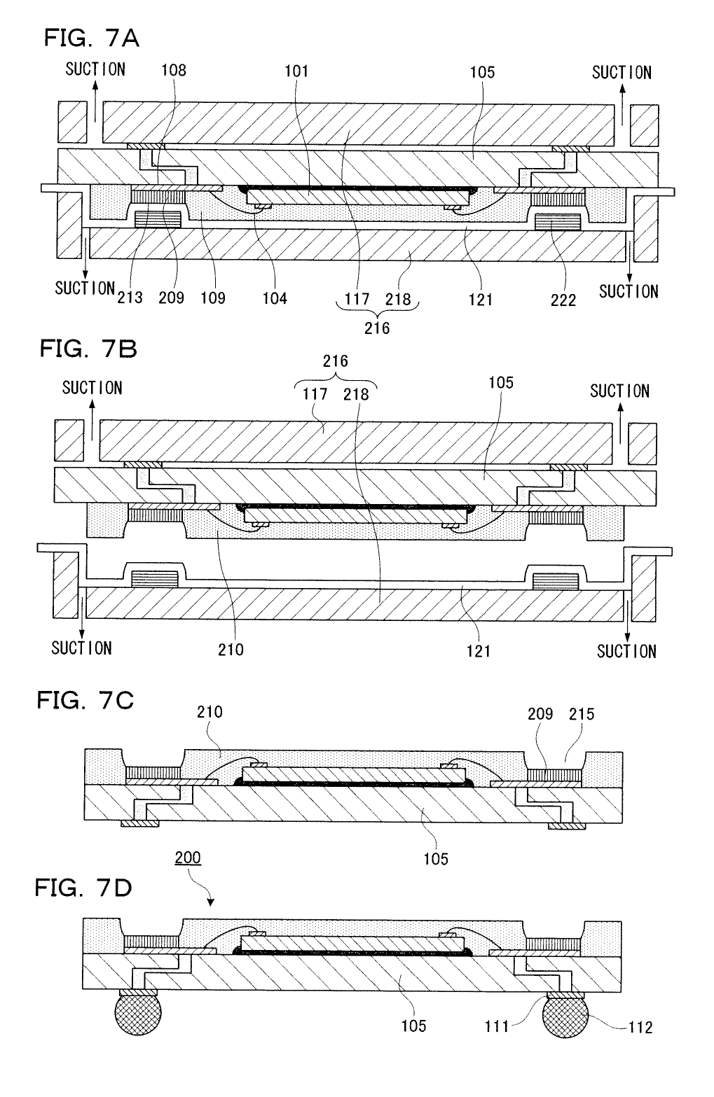

Next, as shown in FIG. 7A, the sealing resin material 109 is subjected to compression molding such that the front side of the wiring board 105 is resin-sealed. Here, the depth of the elevated electrode 209 from the front surface of the sealing resin 210 is set within a range of 5 μm to 300 μm, and preferably at approximately 100 μm.

At this time, the upper surface of the release sheet 121, which is in close contact with the molding surface of the lower die 218, raises the lower die 218 to a position of contact with the front surface of the wiring board 105 held by the upper die 117 while the interior of the cavity region of the lower die 218, in which the molten low-viscosity sealing resin material 109 has accumulated, is subjected to vacuum extraction. The semiconductor chip 101 and the metallic thin wires 104 are buried in the molten low-viscosity sealing resin material 109. A constant clamping pressure is applied to the lower die 218 until the sealing resin material 109 hardens, even after the release sheet 121 has contacted the wiring board 105. The plurality of projections 222 formed in the cavity region of the lower die 218 so as to oppose the platform electrodes 209 contact the plurality of platform electrodes 209 on the wiring board 105 via the release sheet 121 such that tip ends of the plurality of projections 222 are pressed against the plurality of platform electrodes 209. The sealing resin 210 is thus formed such that the front surface of the elevated electrode 209 is exposed to the bottom of the hole 215.

(Step 6)

Next, as shown in FIG. 7B, after the sealing resin 210 has hardened, the lower die 218 is lowered to a height at which the wiring board 105 formed with the sealing resin 210 can be removed. When the lower die 218 is lowered, the release sheet 121 is peeled away easily from the sealing resin 210.

(Step 7)

Next, as shown in FIG. 7C, the plurality of holes 215, which are disposed in the wiring board 105 immediately after its removal from the die 216 so as to correspond respectively to the plurality of platform electrodes 209 in pairs, are formed in the sealing resin 210. The cross-section of each hole 215 takes a narrowing shape having rounded sides such that the opening width is larger than the bottom width and the width decreases toward the elevated electrode 209 at the bottom of the hole 215.

(Step 8)

Next, as shown in FIG. 7D, the plurality of projecting electrodes 112 are fixed on the plurality of rear surface lands 111.

(Summary)

According to the embodiment described above, the plurality of external projecting electrodes can be dropped into the plurality of holes 215 formed in the sealing resin 210, and as a result, the overall height of the PoP type semiconductor device can be suppressed. The reason for this is that when the PoP type semiconductor device is constructed, the plurality of external projecting electrodes are inserted in alignment with the plurality of holes 215 and fixed on the plurality of platform electrodes 209 disposed in the bottom of the plurality of holes 215, and therefore the effect of the height of the plurality of external projecting electrodes on the overall height of the PoP type semiconductor device can be reduced. Further, the depth of the plurality of holes 215 can be adjusted by the plurality of platform electrodes 209 such that even when the sealing resin 210 must be formed thickly, the plurality of external projecting electrodes contact the plurality of platform electrodes 209.

Furthermore, the solder paste that is used when the plurality of external projecting electrodes are fixed can be prevented from leaking out by the plurality of holes 215 formed in the sealing resin 210. Moreover, even when the plurality of external projecting electrodes are formed from multiple pins at a narrow pitch, short-circuits can be prevented from occurring in the platform electrodes 209.

Further, the opening area of the hole 215 is larger than the exposed area of the elevated electrode 209. Moreover, the cross-section of the hole 215 takes a narrowing shape having rounded sides such that the opening width is larger than the bottom width and the width decreases toward the elevated electrode 209 at the bottom of the hole 215. Accordingly, the external projecting electrode can be guided to the elevated electrode 209 disposed in the bottom of the hole 215 easily. As a result, the plurality of external projecting electrodes can be fixed on the plurality of platform electrodes 209 in an accurately positioned state. Furthermore, the external projecting electrode is led to the center of the elevated electrode 209 disposed in the bottom of the hole 215 while being guided by the side wall of the hole 215, and is therefore fixed on the elevated electrode 209 securely. Three-dimensional mounting can be therefore be achieved without mounting defects (open defects). Moreover, in comparison with a case in which a mounting defect (open defect) has occurred, the number of platform electrodes 209 fixed securely on the external projecting electrodes is large, and therefore stress applied to the respective joint parts between the external projecting electrodes and the platform electrodes 209 can be reduced while maintaining sufficient strength in the joint parts. In other words, the reliability of the joint parts between the external projecting electrodes and the platform electrodes 209 can be improved.

Moreover, the platform electrode 209 is constituted by solder, which is a soft material. Therefore, the hole 215 can be formed by pressing a projection of a sealing die (not shown) against the platform electrode 209. Thus, the sealing resin 210 can be formed into a structure in which the plurality of platform electrodes 209 are exposed to the bottoms of the plurality of holes 215 easily.

As a result, it is possible to realize three-dimensional mounting in which height is suppressed, multi-pin/narrow pitch can be achieved, and mounting defects (open defects) do not occur. Moreover, it is possible to a PoP type semiconductor device in which the reliability of the joint parts is high.

Further, during manufacture of the semiconductor device 200, the metallic thin wires 104 are submerged in the material of the sealing resin 210, which has melted sufficiently to reach a low viscosity, at a low speed in (Step 5). Therefore, deformation of the metallic thin wires 104 due to resin flow can be prevented.

Furthermore, in the compression molding method, the sealing resin 210 is formed while the respective front surfaces of the plurality of platform electrodes 209 are pressed against the flexible, elastic release sheet 121. Therefore, the sealing resin 210 can be formed into a structure in which the plurality of platform electrodes 209 are exposed to the bottoms of the plurality of holes 215 easily. Moreover, the sealing resin 210 is formed when the parts corresponding to the plurality of platform electrodes 209 are removed, thereby eliminating the need to perform deburring and cleaning on the sealing resin 210 after the seal is formed.

As a result, a reduction in manufacturing time, a reduction in the number of manufacturing steps, and a corresponding reduction in cost can be realized.

Note that when an FBGA (Fine pitch Ball Grid Array) type semiconductor device is stacked on the semiconductor device 200, the entire structure is substantially identical except for the part of the holes 215 formed in the sealing resin 210. Hence, when constructing a PoP type semiconductor device, the warping shapes of the respective semiconductor devices during reflow are different, and therefore mounting defects (open defects) do not occur.

### Third Embodiment

A third embodiment of the present invention will be described below. Note that identical constitutional elements to the first embodiment have been allocated identical reference numerals, and description thereof has been omitted.

(Constitution)

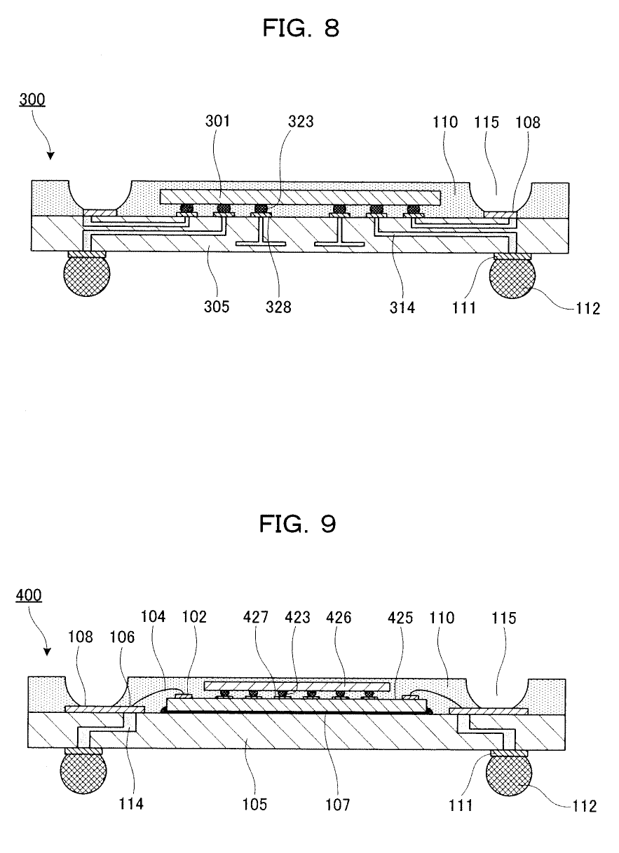

As shown in FIG. 8, a semiconductor device 300 differs from the semiconductor device 100 according to the first embodiment in that a semiconductor chip 301 is mounted on a wiring board 305 by a flip chip method.

The semiconductor chip 301 includes a plurality of bumps 323 instead of the plurality of electrode terminals 102 of the first embodiment. Here, the plurality of bumps 323 are disposed on a rear surface of the semiconductor chip 301 and electrically connected to an integrated circuit (not shown).

The wiring board 305 includes a plurality of semiconductor chip lands 328 instead of the plurality of connection terminals 106 of the first embodiment. Here, the plurality of semiconductor chip lands 328 are disposed in a front surface central region of the wiring board 305 so as to correspond respectively to the plurality of bumps 323 on the semiconductor chip 301 in pairs, and are electrically connected to the plurality of front surface lands 108 and the plurality of rear surface lands 111 via vias 314 and so on.

(Summary)

According to the embodiment described above, in the semiconductor device 300, the semiconductor chip lands 328 are not disposed on the outside of the semiconductor chip mounting region. Hence, in comparison with the semiconductor device 100 of the first embodiment, the semiconductor chip mounting region can be enlarged such that a chip of a larger size can be mounted thereon.

### Fourth Embodiment

A fourth embodiment of the present invention will be described below. Note that identical constitutional elements to the first embodiment have been allocated identical reference numerals, and description thereof has been omitted.

(Constitution)

As shown in FIG. 9, a semiconductor device 400 differs from the semiconductor device 100 according to the first embodiment in that a second semiconductor chip 426 having a smaller projected area than a first semiconductor chip 425 is mounted on the first semiconductor chip 425 using a flip chip method.

The first semiconductor chip 425 includes an integrated circuit (not shown) and a plurality of electrode pads 427. Taking the side on which the plurality of electrode pads 427 are disposed as a front side, the first semiconductor chip 425 is mounted on a front surface central region of the wiring board 105 by the adhesive 107. Here, the plurality of electrode pads 427 are disposed in the front surface central region of the first semiconductor chip 425 and electrically connected to the integrated circuit (not shown).

The second semiconductor chip 426 includes an integrated circuit (not shown) and a plurality of bumps 423. Taking the side on which the plurality of bumps 423 are disposed as a lower side, the second semiconductor chip 426 is mounted on the front side of the first semiconductor chip 425. Here, the plurality of bumps 423 are formed from a similar material to the plurality of bumps 323 of the third embodiment, and are electrically connected to the integrated circuit (not shown). Further, the plurality of bumps 423 are disposed in a front surface central region of the second semiconductor chip 426 so as to correspond respectively to the plurality of electrode pads 427 in pairs, and are electrically connected to the plurality of electrode pads 427.

(Summary)

According to the embodiment described above, in the semiconductor device 400, a plurality of semiconductor chips are stacked. Therefore, a PoP type semiconductor device having a higher density than the semiconductor device 100 according to the first embodiment can be realized.

### Fifth Embodiment

A fifth embodiment of the present invention will be described below. Note that identical constitutional elements to the first embodiment have been allocated identical reference numerals, and description thereof has been omitted.

(Constitution)

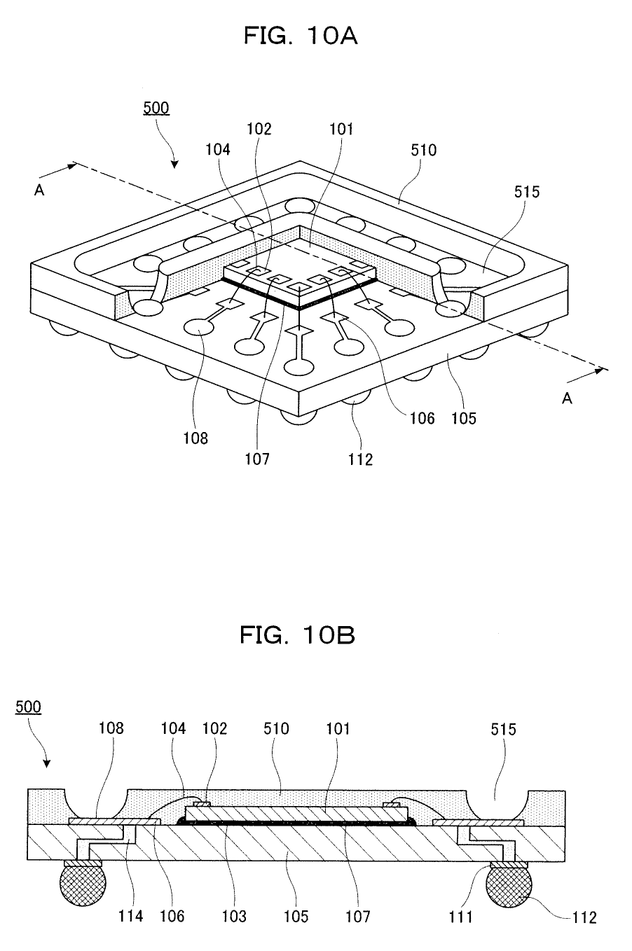

As shown in FIGS. 10A and 10B, a semiconductor device 500 differs from the semiconductor device 100 according to the first embodiment on the following point (1).

Note that in FIG. 10A, a part of a sealing resin 510 has been removed to make the structure of the semiconductor device 500 easier to see.

(1) A groove 515 linking the plurality of front surface lands 108 is formed in the sealing resin 510 instead of the plurality of holes 115.

Here, the groove 515 is formed in the sealing resin 510 with a shape and dimensions that allow the plurality of external projecting electrodes to be inserted therein and such that the plurality of front surface lands 108 disposed further toward the inner side than the front surface of the semiconductor chip 101 are exposed. The cross-section of the groove 515 takes a narrowing shape having rounded sides such that an opening width is larger than a bottom width and the width decreases toward the front surface land 108 at the bottom of the groove 515. In other words, the ring-shaped groove 515 is formed in the sealing resin 510 to allow the plurality of external projecting electrodes to be fixed on the plurality of front surface lands 108.

Note that an embankment-shaped projection is formed in the cavity region of the lower die 118 of the die 116 in accordance with the shape and dimensions of the groove 515 instead of the projections 122.

(Summary)

According to the embodiment described above, the plurality of external projecting electrodes can be dropped into the groove 515 formed in the sealing resin 510, and as a result, the overall height of the PoP type semiconductor device can be suppressed. The reason for this is that when the PoP type semiconductor device is constructed, the plurality of external projecting electrodes are inserted in accordance with the groove 515 and fixed on the plurality of front surface lands 108 disposed in the bottom of the groove 515, and therefore the effect of the height of the plurality of external projecting electrodes on the overall height of the PoP type semiconductor device can be reduced.

### Sixth Embodiment

A sixth embodiment of the present invention will be described below. Note that identical constitutional elements to the second embodiment have been allocated identical reference numerals and description thereof has been omitted.

(Constitution)

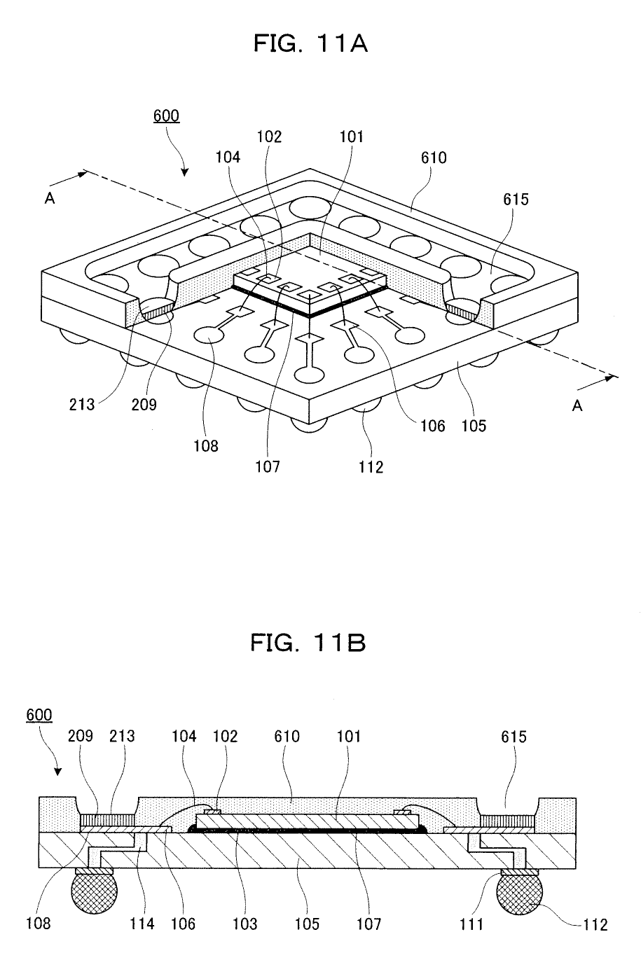

As shown in FIGS. 11A and 11B, a semiconductor device 600 differs from the semiconductor device 200 according to the second embodiment on the following point (1).

Note that in FIG. 11A, a part of the elevated electrode 209 and a sealing resin 610 has been removed to make the structure of the semiconductor device 600 easier to see.

(1) A groove 615 linking the plurality of platform electrodes 209 is formed in the sealing resin 610 instead of the plurality of holes 215.

Here, the groove 615 is formed in the sealing resin 610 with a shape and dimensions that allow the plurality of external projecting electrodes to be inserted therein and such that the plurality of platform electrodes 209 formed on the plurality of front surface lands 108 disposed further toward the inner side than the front surface of the semiconductor chip 101 are exposed. The cross-section of the groove 615 takes a narrowing shape having rounded sides such that an opening width is larger than a bottom width and the width decreases toward the elevated electrode 209 at the bottom of the groove 615. In other words, the ring-shaped groove 615 is formed in the sealing resin 610 to allow the plurality of external projecting electrodes to be fixed on the plurality of platform electrodes 209.

Note that an embankment-shaped projection is formed in the cavity region of the lower die 218 of the die 216 in accordance with the shape and dimensions of the groove 615 instead of the projections 222.

(Summary)

According to the embodiment described above, the plurality of external projecting electrodes can be dropped into the groove 615 formed in the sealing resin 610, and as a result, the overall height of the PoP type semiconductor device can be suppressed. The reason for this is that when the PoP type semiconductor device is constructed, the plurality of external projecting electrodes are inserted in accordance with the groove 615 and fixed on the plurality of platform electrodes 209 disposed in the bottom of the groove 615, and therefore the effect of the height of the plurality of external projecting electrodes on the overall height of the PoP type semiconductor device can be reduced. Further, the depth of the groove 615 can be adjusted by the plurality of platform electrodes 209 such that even when the sealing resin 610 must be formed thickly, the plurality of external projecting electrodes contact the plurality of platform electrodes 209.

### Other Embodiments

The semiconductor chip 101 may be mounted on the semiconductor device 100 using a flip chip method. Further, the semiconductor chip 151 may be mounted on the BGA type semiconductor device 150 using a flip chip method.

Two or more semiconductor chips may be mounted on the semiconductor device 100. Further, the PoP type semiconductor device may be constituted by three or more stacked semiconductor devices 100.

Instead of silicon, a single-element material such as germanium or graphite or a compound material such as gallium arsenide or zinc telluride may be used as the base material of the semiconductor chip 101.

Instead of gold wire, copper wire, aluminum wire, silver wire, and so on may be used as the metallic thin wire 104.

A resin substrate formed by submerging any one of epoxy resin, phenol resin, polyimide resin, and so on in glass fiber and curing the resulting mixture may be used as a substrate for forming the wiring board 105. Further, a resin substrate formed by submerging any one of epoxy resin, phenol resin, polyimide resin, and so on in fiber constituted by an organic substance, such as Kepler fiber, and curing the resulting mixture may be used. A resin substrate employing BT resin or a liquid crystal polymer may also be used. Further, a single-layer resin substrate or a multi-layer resin substrate may be used. Furthermore, a ceramic substrate constituted by any one of aluminum oxide, aluminum nitride, glass, quartz, and so on may be used. Further, a single-layer ceramic substrate or a laminated ceramic structure may be used.

Briefly, the wiring board 105 is manufactured as follows. A substrate formed with a conductive film on either surface thereof is subjected to photolithography to form a conductive film on the front surface in a predetermined shape. The wiring pattern, the connection terminals 106, and the front surface lands 108 are thus formed on the front surface. A conductive film is then formed similarly on the rear surface in a predetermined shape through photolithography. The wiring pattern and the rear surface lands 111 are thus formed on the rear surface. The wiring patterns on the two surfaces are then electrically connected via the vias 114. An insulating film made of solder resist or the like is then formed on both surfaces of the board, excluding the connection terminals 106, the front surface lands 108, and the rear surface lands 111.

Copper foil may be used as the conductive film. Further, a metallic layer may be formed on the copper foil. Here, the metallic layer may include at least one of nickel, solder, gold, silver, palladium, and so on.

Further, when the substrate of the wiring board 105 is constituted by a sintered material such as aluminum oxide or aluminum nitride, the conductive film may be constituted by a refractory metal such as tungsten, manganese, molybdenum, and tantalum. At this time, the conductive film may be covered with a conductive material such as gold, silver, copper, or palladium.

Further, when the substrate of the wiring board 105 is constituted by a transparent material such as glass or quartz, the conductive film may be constituted by a transparent conductive material such as tin chloride.

An intermediate wiring layer constituted by one or more layers may be formed between the conductive films on the two surfaces of the substrate of the wiring board 105.

The adhesive 107 may include at least one of epoxy resin, polyimide resin, and acrylic resin. Further, a gold-silicon eutectic or solder may be used. A substance exhibiting conductivity or an insulating property may also be used. Further, a substance that is blended with a photoinitiator so as to exhibit an ultraviolet curing property may be used. For example, an epoxy-based conductive adhesive to which silver filler has been added may be used. Further, a paste-form adhesive or a tacky sheet-form adhesive may be used.

When the adhesive 107 is a paste-form adhesive, the paste-form adhesive may be printed onto the semiconductor chip mounting region of the wiring board 105 at an appropriate thickness through screen printing, or applied at multiple points in an appropriate amount using a multi-nozzle dispenser. When the adhesive 107 is a tacky sheet, a tacky sheet of an appropriate size may be disposed in the semiconductor chip mounting region of the wiring board 105.

Instead of an epoxy resin, a biphenyl resin, a phenol resin, a silicone resin, a cyanate ester resin, and so on may be used as the sealing resin material 109. Further, the sealing resin material 109 may include at least one of a bisphenol A type epoxy resin, a bisphenol F type epoxy resin, a biphenyl type epoxy resin, a naphthalene type epoxy resin, and so on. Further, instead of being granular, the sealing resin material 109 may take a liquid form, a mini-tablet form, a sheet form, and so on.

The projecting electrode 112 may be constituted by any one of an Sn—Ag—Cu-based solder material, an Sn—Pb-based solder material, an Sn—Ag—Bi—In-based solder material, an Sn—Zn—Bi-based solder material, and so on. Further, the projecting electrode 112 may be formed from a copper core portion having a solder layer on an upper layer portion or the entire surface thereof. The projecting electrode 112 may also be formed from a nickel core portion having a solder layer on an upper layer portion or the entire surface thereof.

As the release sheet 121, a sheet constituted by any one of a polytetrafluoroethylene resin (PTFE), an ethylene tetrafluoroethylene copolymer resin (ETFE), a tetrafluoroethylene perfluoropropylene copolymer resin (FEP), a polyvinylidene fluoride resin (PBDF), a polyethylene terephthalate resin (PET), a polypropylene resin (PP), and silicone rubber (SR). Further, the release sheet 121 may be single-layered or laminated.

Any one of a zinc-based alloy, a tin-based alloy, a bismuth-based alloy, and a silver-based alloy may be used as the material of the elevated electrode 209. Further, the elevated electrode 209 may be formed by laminating a metallic film formed from any one of gold, palladium, silver, and solder onto a copper or nickel pedestal or covering the pedestal with the metallic film.

The elevated electrode 209 may have a two-layer structure. The lower layer may be constituted by one of copper, an iron-nickel alloy, and nickel, and the upper layer may be constituted by a metallic layer exhibiting superior ductility and malleability, such as solder or gold. Further, the elevated electrode 209 may be formed by forming a layer constituted by solder or gold on the surface of a core portion constituted by any one of copper, an iron-nickel alloy, and nickel. The elevated electrode 209 may also be a stud bump obtained by overlapping gold balls in a plurality of stages during wire bonding using both ultrasonic waves and thermal compression bonding.

The bump 323 may be formed from any one of a zinc-based alloy, a tin-based alloy, a bismuth-based alloy, and a silver-based alloy. Further, the bump 323 may be formed by forming a solder layer on an upper layer portion or the entire front surface of a core portion constituted by copper and formed by electrolytic/non-electrolytic plating. The bump 323 may also be formed by forming a solder layer on an upper layer portion or the entire front surface of a core portion constituted by nickel and formed by electrolytic/non-electrolytic plating.

What is claimed is:

1. A semiconductor device on which another semiconductor device can be stacked, comprising:
a wiring board having a plurality of front surface lands disposed on a front surface and a plurality of rear surface lands disposed on a rear surface;
a semiconductor chip formed with an integrated circuit and a plurality of electrode terminals electrically connected to the integrated circuit; and
a sealing resin that covers a front side of the wiring board when the semiconductor chip is mounted on the front side of the wiring board such that the plurality of front surface lands and the plurality of rear surface lands are electrically connected to the plurality of electrode terminals,
wherein a recess portion having a shape and dimensions that allow a plurality of projecting electrodes of the other semiconductor device to be inserted therein is formed in the sealing resin such that the plurality of front surface lands disposed further toward an inner side than a front surface of the semiconductor chip are exposed.

2. The semiconductor device according to claim 1, wherein the recess portion is constituted by a plurality of holes formed to correspond respectively to the plurality of front surface lands so as to form pairs therewith.

3. The semiconductor device according to claim 2, wherein a cross-section of the hole takes a narrowing shape having rounded sides such that an opening width is larger than a bottom width and the width decreases toward the front surface land at the bottom of the hole.

4. The semiconductor device according to claim 2, wherein an opening area of the hole is larger than an exposed area of the front surface land.

5. The semiconductor device according to claim 1, wherein the recess portion is constituted by a groove formed to link the plurality of front surface lands.

6. The semiconductor device according to claim 5, wherein a cross-section of the groove takes a narrowing shape having rounded sides such that an opening width is larger than a bottom width and the width decreases toward the front surface land at the bottom of the groove.

7. A semiconductor device on which another semiconductor device can be stacked, comprising:
a wiring board having a plurality of front surface lands disposed on a front surface and a plurality of rear surface lands disposed on a rear surface;
a semiconductor chip formed with an integrated circuit and a plurality of electrode terminals electrically connected to the integrated circuit;
a plurality of platform electrodes formed on the plurality of front surface lands so as to correspond respectively to the plurality of front surface lands in pairs and project from the front surface of the wiring board; and
a sealing resin that covers a front side of the wiring board when the semiconductor chip is mounted on the front side of the wiring board such that the plurality of front surface lands and the plurality of rear surface lands are electrically connected to the plurality of electrode terminals,
wherein a recess portion having a shape and dimensions that allow a plurality of projecting electrodes of the other semiconductor device to be inserted therein is formed in the sealing resin such that the plurality of platform electrodes formed on the plurality of front surface lands disposed further toward an inner side than a front surface of the semiconductor chip are exposed.

8. The semiconductor device according to claim 7, wherein the recess portion is constituted by a plurality of holes formed to correspond respectively to the plurality of platform electrodes so as to form pairs therewith.

9. The semiconductor device according to claim 8, wherein a cross-section of the hole takes a narrowing shape having rounded sides such that an opening width is larger than a bottom width and the width decreases toward the elevated electrode at the bottom of the hole.

10. The semiconductor device according to claim 8, wherein an opening area of the hole is larger than an exposed area of the elevated electrode.

11. The semiconductor device according to claim 7, wherein the recess portion is constituted by a groove formed to link the plurality of platform electrodes.

12. The semiconductor device according to claim 11, wherein a cross-section of the groove takes a narrowing shape having rounded sides such that an opening width is larger than a bottom width and the width decreases toward the elevated electrode at the bottom of the groove.

13. The semiconductor device according to claim 7, wherein the elevated electrode is constituted by solder.

14. A manufacturing method for a semiconductor device on which another semiconductor device can be stacked, comprising:
a first step for preparing a wiring board having a plurality of front surface lands disposed on a front surface and a plurality of rear surface lands disposed on a rear surface;
a second step for mounting a semiconductor chip formed with an integrated circuit and a plurality of electrode terminals electrically connected to the integrated circuit on a front side of the wiring board and electrically connecting the plurality of front surface lands and the plurality of rear surface lands to the plurality of electrode terminals; and
a third step for forming a sealing resin that covers the front side of the wiring board when the semiconductor chip is mounted on the front side of the wiring board such that the plurality of front surface lands and the plurality of rear surface lands are electrically connected to the plurality of electrode terminals using a compression molding method while pressing a front surface of the plurality of front surface lands against a release sheet possessing flexibility and elasticity,
wherein, in the third step, a recess portion having a shape and dimensions that allow a plurality of projecting electrodes of the other semiconductor device to be inserted therein is formed in the sealing resin using a die having projecting portions corresponding respectively to the plurality of projecting electrodes in a cavity such that the plurality of front surface lands, which are disposed further toward an inner side than a front surface of the semiconductor chip, are exposed.

15. A manufacturing method for a semiconductor device on which another semiconductor device can be stacked, comprising:
a first step for preparing a wiring board having a plurality of front surface lands disposed on a front surface and a plurality of rear surface lands disposed on a rear surface;
a second step for forming a plurality of platform electrodes that correspond respectively to the plurality of front surface lands in pairs and project from the front surface of the wiring board on the plurality of front surface lands;
a third step for mounting a semiconductor chip formed with an integrated circuit and a plurality of electrode terminals electrically connected to the integrated circuit on a front side of the wiring board and electrically connecting the plurality of front surface lands and the plurality of rear surface lands to the plurality of electrode terminals; and
a fourth step for forming a sealing resin that covers the front side of the wiring board when the semiconductor chip is mounted on the front side of the wiring board such that the plurality of front surface lands and the plurality of rear surface lands are electrically connected to the plurality of electrode terminals using a compression molding method while pressing a front surface of the plurality of platform electrodes against a release sheet possessing flexibility and elasticity,
wherein, in the fourth step, a recess portion having a shape and dimensions that allow a plurality of projecting electrodes of the other semiconductor device to be inserted therein is formed in the sealing resin using a die having projecting portions corresponding respectively to the plurality of projecting electrodes in a cavity such that the plurality of platform electrodes formed on the plurality of front surface lands, which are disposed further toward an inner side than a front surface of the semiconductor chip, are exposed.
